(19) United States
(12) Patent Application Publication
(10) Pub. No.: US 2006/0284286 A1
(43) Pub. Date: Dec. 21, 2006

(54) Flashless molding of integrated circuit devices

(75) Inventor: Teiji Kamino, Beppu-city (JP)

Correspondence Address: TEXAS INSTRUMENTS INCORPORATED, P O BOX 655474, M/S 3999, DALLAS, TX, 75265, US

(73) Assignee: Texas Instrument Inc.

(21) Appl. No.: 11/157,032

(22) Filed: Jun. 20, 2005

(51) Int. Cl. H01L 23/495

(52) U.S. Cl. 257/666

(57) ABSTRACT

A method for encapsulating an IC package is performed, in one example embodiment, by providing a lead frame member including the IC chip mounted on a portion of the lead frame member, wherein the lead frame member further includes a plurality of apertures disposed substantially around the mounted IC chip. The plurality of apertures in the lead frame member is then filled with an isolation material by dispensing the isolation material in each of the plurality of apertures. The lead frame member is then placed into a mold including a mold cavity such that the IC package including the plurality of apertures are disposed in the mold cavity. A mold compound is then injected into the mold cavity in a manner that fills the mold cavity with the mold compound to form an encapsulant over the IC package and the plurality of the apertures.

### TECHNICAL FIELD OF THE INVENTION

The present invention relates generally to integrated circuit (IC) packages, and more particularly relates to injection molding of IC packages.

### BACKGROUND OF THE INVENTION

Integrated circuits are typically encapsulated in a package of a suitable material, such as epoxy, from which the conductive leads project laterally and then downwards. However, other lead configurations are also in common use. Typically, an IC chip, i.e., a semiconductor element, is mounted on a lead frame member, which further includes a plurality of leads, a tie bar, a plurality of auxiliary leads, a support stay portion, and a plurality of apertures, such as through holes that facilitate in the manufacturing of IC packages.

The encapsulation of the IC is typically performed by placing the lead frame member including the IC chip in a mold cavity and then injecting a suitable molding compound, such as an epoxy, into the mold cavity. During the encapsulation of the IC the mold cavity is typically kept hot so that the mold compound flows into all the portions of the mold cavity. However, this can result in a leak of the mold compound via the through holes in the lead frame member resulting in the formation of mold flash substantially around the through holes and across from the mold cavity. The mold flash formed around the through holes can significantly interfere in subsequent surface mount operations that attach the encapsulated IC to the printer circuit board using solder joints. Further, the mold flash can affect the solder joint quality.

### SUMMARY OF THE INVENTION

According to an aspect of the present invention there is provided a method for encapsulating an IC chip, the method including the steps of providing a lead frame member including the IC chip mounted on a portion of the lead frame member, and wherein the lead frame member further includes a plurality of apertures disposed substantially around the mounted IC chip, filling the plurality of apertures in the lead frame member with an isolation material by dispensing the isolation material in each of the plurality of apertures, placing the lead frame member into a mold including a mold cavity such that the IC package includes the plurality of apertures are disposed in the mold cavity, and injecting a mold compound into the mold cavity in a manner that fills the mold cavity with the mold compound, thereby forming an encapsulant over the IC package and the plurality of the apertures.

According to another aspect of the present invention there is provided a method for encapsulating an IC chip, the method includes the steps of providing a substrate including an IC chip mounted on a portion of the substrate, and wherein the substrate further includes a plurality of apertures disposed substantially around the mounted IC chip, filling the plurality of apertures in the substrate with an isolation material by dispensing the isolation material in each of the plurality of apertures, placing the substrate into a mold cavity that is located within a mold such that the IC package including the plurality of apertures in the substrate is disposed in the mold cavity, and introducing a mold compound into the mold cavity in a manner that fills the mold cavity with the mold compound, thereby forming an encapsulant over the IC package and the plurality of the apertures.

According to another aspect of the present invention there is provided an IC package, wherein the IC package includes a lead frame member including an IC chip mounted on a portion of the lead frame member, wherein the lead frame member further includes a plurality of apertures disposed substantially around the mounted IC chip, and wherein the plurality of apertures are substantially filled with an isolation material. The IC package further includes a molded encapsulant disposed substantially over the IC comprising a plastic material.

According to another aspect of the present invention there is provided a semiconductor package, wherein the semiconductor package includes a lead frame member having a semiconductor element mounted circuit side down thereon, wherein the lead frame member has a side portion substantially around the semiconductor element, wherein the lead frame member includes a plurality of apertures that are disposed substantially around a periphery of the semiconductor element, and wherein each of the plurality of apertures is filled with an isolation material. Further, the semiconductor package includes a plurality of leads arranged along and extending substantially from the side portion of the lead frame member. Furthermore, the semiconductor package also includes a molded encapsulant that is disposed substantially over the semiconductor element comprising a plastic material.

### BRIEF DESCRIPTION OF THE DRAWINGS

FIG. 1 is a flowchart illustrating an example method of flashless encapsulation of IC according to an embodiment of the present invention.

FIGS. 2-4 illustrate sectional views of sequential processing steps of FIG. 1, showing encapsulating of an IC according to an embodiment of the present invention.

FIG. 5 illustrates a bottom view of the IC package according to an embodiment of the present invention.

### DETAILED DESCRIPTION OF THE INVENTION

In the following detailed description of the embodiments of the invention, reference is made to the accompanying drawings that form a part hereof, and in which are shown by way of illustration specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined only by the appended claims.

The terms “substrate” and “lead frame member” are used interchangeably throughout the document. Further, the terms “semiconductor package” and “IC package” are used interchangeably throughout the document.

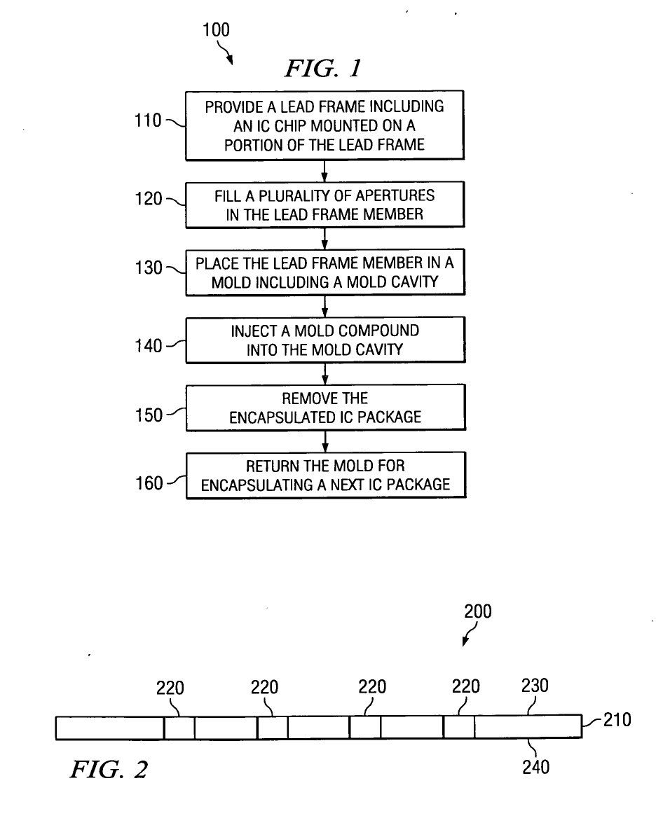

FIG. 1 is a flowchart illustrating an example embodiment of a method 100 for encapsulating an IC. At step 110, the method 100, in this example embodiment, begins by providing a lead frame member that includes an IC chip mounted on a portion of the lead frame member. In these embodiments, the lead frame member further includes a plurality of apertures disposed substantially around the mounted IC chip. Exemplary shapes of the plurality of apertures include a circuit shape, an elliptical shape, and an elongated shape. In some embodiments, the lead frame member includes a plurality of leads disposed substantially around the periphery of the IC package.

Referring now to FIG. 2, the block diagram 200 illustrates an example embodiment of the lead frame member 210. Exemplary lead frame member material includes Cu+NiPdu. In some embodiments, the lead frame member base material is Cu (that is materials, such as FTEC64T, MF202, OLIN194 and so on). As shown in FIG. 2, the lead frame member 200 includes the plurality of apertures 220. Referring now to FIG. 5, the schematic diagram 500 shows the bottom view of the lead frame member 210 including the plurality of apertures 220. As shown in FIG. 5, each of the apertures is a through hole that extends from a bottom surface of the lead frame member 230 to the top surface of the lead frame member 240 (shown in FIG. 2).

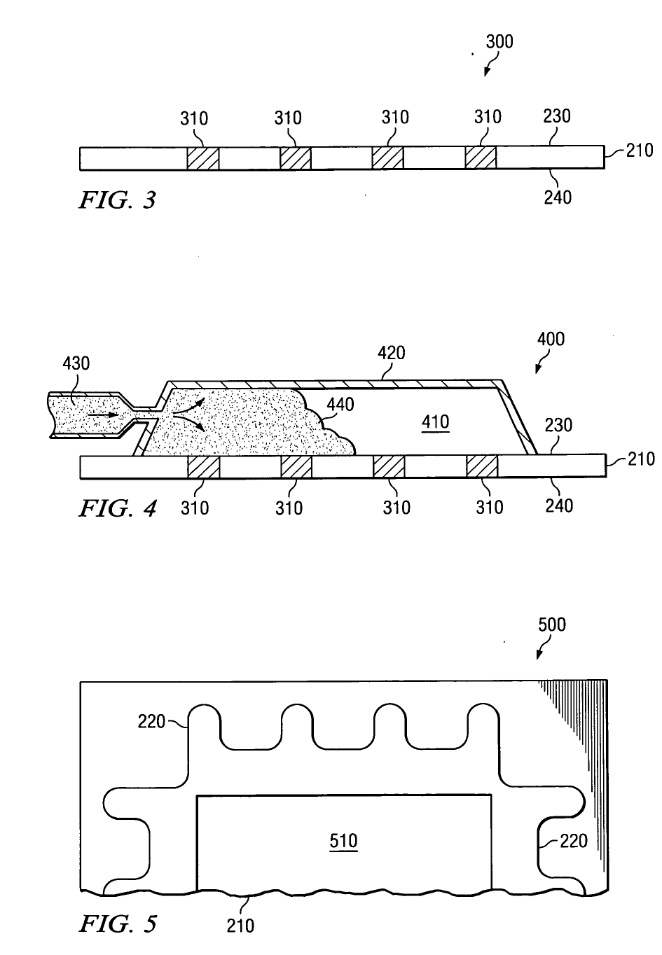

At step 120, the plurality of apertures in the lead frame member is filled with an isolation material by dispensing the isolation material in each of the plurality of apertures. Referring now to FIG. 3, the block diagram 300 illustrates an example embodiment of the plurality of the apertures 220 filled with the isolation material 310. Referring now to FIG. 5, the bottom view of the schematic diagram 500 shows the filled plurality of apertures 220. Exemplary isolation material includes a solder resist such as epoxy resin.

At step 130, the lead frame member is placed into a mold cavity of a mold such that the IC package along with the plurality of the apertures is disposed in the mold cavity. Referring now to FIGS. 4 and 5, the block diagrams 400 and 500 illustrate an example embodiment of the IC package 510 along with the plurality of apertures 220 in the lead frame member 210 placed in the mold cavity 410 of the mold 420.

At step 140, a mold compound is injected into the mold cavity in a manner that fills the mold cavity with the mold compound so that an encapsulant is formed over the IC package along with the plurality of apertures. Referring now to FIG. 4, the schematic diagram 400 illustrates an example embodiment of injecting the mold compound 440, in a direction 430, into the mold cavity 410 to form the encapsulant over the IC package 510 (shown in FIG. 5) and the plurality of apertures 210. Exemplary mold compound includes a plastic material, such as an epoxy.

At step 150, the encapsulated IC package disposed in the lead frame member is removed from the mold cavity. At step 160, the mold is returned for encapsulating a next lead frame member including an IC package along with a plurality of apertures.

The above-described methods and apparatus provide various techniques to encapsulate an IC. The above encapsulation process of the IC improves the formation of the solder joint quality obtained in subsequent printed circuit board assembly operations.

It is to be understood that the above description is intended to be illustrative, and not restrictive. Many other embodiments will be apparent to those of skill in the art upon reviewing the above description. The scope of the subject matter should, therefore, be determined with reference to the following claims, along with the full scope of equivalents to which such claims are entitled.

As shown herein, the present invention can be implemented in a number of different embodiments, including various methods, an apparatus, and a system. Other embodiments will be readily apparent to those of ordinary skill in the art. The elements, algorithms, and sequence of operations can all be varied to suit particular requirements. The operations described above with respect to the method illustrated in FIG. 1 can be performed in a different order from those shown and described herein.

FIGS. 1-5 are merely representational and are not drawn to scale. Certain proportions thereof may be exaggerated, while others may be minimized. FIGS. 1-5 illustrate various embodiments of the invention that can be understood and appropriately carried out by those of ordinary skill in the art.

It is emphasized that the Abstract is provided to comply with 37 C.F.R. § 1.72(b) requiring an Abstract that will allow the reader to quickly ascertain the nature and gist of the technical disclosure. It is submitted with the understanding that it will not be used to interpret or limit the scope or meaning of the claims.

In the foregoing detailed description of the embodiments of the invention, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the detailed description of the embodiments of the invention, with each claim standing on its own as a separate preferred embodiment.

1. A method for fabricating an IC package comprising:
providing a lead frame member including the IC chip mounted on a portion of the lead frame member, and wherein the lead frame member further includes a plurality of apertures disposed substantially around the mounted IC chip;
filling the plurality of apertures in the lead frame member with an isolation material by dispensing the isolation material in each of the plurality of apertures;
placing the lead frame member into a mold including a mold cavity such that the IC package including the plurality of apertures are disposed in the mold cavity; and
injecting a mold compound into the mold cavity in a manner that fills the mold cavity with the mold compound, thereby forming an encapsulant over the IC package and the plurality of the apertures.

2. The method of claim 1, wherein the plurality of apertures have a shape selected from the group consisting of circular shape, elliptical shape, and elongated shape.

3. The method of claim 1, wherein the lead frame member further comprises a plurality of leads disposed substantially around the periphery of the IC package.

4. The method of claim 1, further comprising:
removing the encapsulated IC package mounted on the lead frame member from the mold cavity.

5. The method of claim 1, further comprising:
returning the mold for encapsulating a next IC package mounted on a portion of a lead frame member.

6. A method comprising:
providing a substrate including an IC chip mounted on a portion of the substrate, and wherein the substrate further includes a plurality of apertures disposed substantially around the mounted IC chip;
filling the plurality of apertures in the substrate with an isolation material by dispensing the isolation material in each of the plurality of apertures;
placing the substrate into a mold cavity that is located within a mold such that the IC package including the plurality of apertures in the substrate is disposed in the mold cavity; and
introducing a mold compound into the mold cavity in a manner that fills the mold cavity with the mold compound, thereby forming an encapsulant over the IC package and the plurality of the apertures.

7. The method of claim 6, wherein the plurality of apertures have a shape selected from the group consisting of circular shape, elliptical shape, and elongated shape.

8. The method of claim 6, wherein, in introducing the mold compound into the mold cavity, the mold compound comprises an epoxy.

9. An integrated circuit (IC) package comprising:
A lead frame member including an IC chip mounted on a portion of the lead frame member, wherein the lead frame member further includes a plurality of apertures disposed substantially around the mounted IC chip, wherein the plurality of apertures are substantially filled with an isolation material; and
a molded encapsulant disposed substantially over the IC comprising a plastic material.

10. The IC package of claim 9, wherein the plastic material comprises an epoxy.

11. The IC package of claim 9, wherein the lead frame member further comprises a plurality of leads extending away from an outer periphery of the IC chip.

12. A semiconductor package comprising:
a lead frame member having a semiconductor element, mounted circuit side down thereon, wherein the lead frame member having a side portion substantially around the semiconductor element, wherein the lead frame member includes a plurality of apertures that are disposed substantially around a periphery of the semiconductor element, and wherein each of the plurality of apertures is filled with an isolation material;
a plurality of leads arranged along and extending substantially from the side portion of the lead frame member; and
a molded encapsulant disposed substantially over the semiconductor element comprising a plastic material.

13. The semiconductor package of claim 12, wherein the plastic material comprises an epoxy.

14. The semiconductor package of claim 12, wherein each of the plurality of leads are substantially equally spaced from one another, and wherein the plurality of leads are linearly disposed along the side portion of the lead frame member.

15. The semiconductor package of claim 12, wherein the isolation material comprises an epoxy resin.
